(19) United States
(12) Patent Application Publication
(10) Pub. No.: US 2025/0273928 A1
(43) Pub. Date: Aug. 28, 2025

(54) OPTICAL MODULE AND OPTICAL COMMUNICATION DEVICE

(71) Applicant: InnoLight Technology (Suzhou) Ltd., Suzhou , Jiangsu (CN)

(72) Inventors: XIAN ZHOU, Suzhou , Jiangsu (CN); SHAMEI SHI, Suzhou , Jiangsu (CN); PENG CHEN, Suzhou , Jiangsu (CN); DengQun YU, Suzhou , Jiangsu (CN)

(21) Appl. No.: 18/857,463

(22) PCT Filed: Feb. 8, 2023
(86) PCT No.: PCT/CN2023/074911

§ 371 Date: Oct. 17, 2024

(30) Foreign Application Priority Data
Apr. 20, 2022 (CN) 202220913573.3

(51) Int. Cl. H01S 5/024; H01S 5/02315

(52) U.S. Cl. CPC H01S 5/02469; H01S 5/02315

(57) ABSTRACT

An optical module (100) and an optical communication device. The optical module (100) comprises a first housing (110), a second housing (120), an optoelectronic component (130) and a circuit board (140). The optoelectronic component (130) and the circuit board (140) are both mounted between the first housing (110) and the second housing (120). A bottom wall (150) on the side of the first housing (110) facing the second housing (120) is provided with a first protrusion (111), the first protrusion (111) being provided with a first matching surface (112); and a bottom wall (150) of the second housing (120) is provided with a second matching surface (122), the first matching surface (112) being thermally connected to the second matching surface (122). Heat generated by the optoelectronic component (130) during operation can be conducted to the first housing (110) by means of the first protrusion (111), and heat concentrated on the second housing (120) can also be conducted to the first housing (110) by means of the first protrusion (111) and can be conducted to the outside by means of the bottom wall (150) of the first housing (110). Compared with a traditional air heat conduction method, the contact area between the first housing (110) and the second housing (120) is increased, such that the heat conduction rate is accelerated, and the heat concentrated on the second housing (120) can thus be quickly dissipated, thereby significantly improving the heat dissipation effect of the optical module (100).

### CROSS-REFERENCE TO RELATED PATENT APPLICATION

This application claims priority to the Chinese patent application filed with the China Patent Office on Apr. 20, 2022, with the application No. 202220913573.3 and the invention name “optical module and optical communication device”, the entire content of which is incorporated into this application by reference.

### FIELD OF THE DISCLOSURE

The present disclosure relates to the field of optical communication technology, and in particular to an optical module and an optical communication device.

### BACKGROUND OF THE DISCLOSURE

With the continuous development of optical communication technology, optical modules have become crucial carriers for transmission between switches and devices. Compared to copper cables, optical modules offer greater efficiency and security in transmission, thus playing a vital role in fiber optic communications. However, during communication, optical modules generate a significant amount of heat. To ensure the proper functioning of optical communication, it is essential to dissipate the heat generated by the optical modules promptly.

In the existing technology, to dissipate heat from optical modules, a primary cooling surface on one of external surfaces of the module is typically used during installation. Heat from within the optical module is conducted to the external environment through a heat sink or fan assembly attached to the primary cooling surface. However, the internal heat of the optical module is transferred to the primary cooling surface through air conduction, which is inefficient. As a result, the surface of the optical module that is farther from the primary cooling surface maintains a consistently high temperature, and the heat concentrated on the surface is not easily dissipated, which leads to poor cooling performance of the optical module, and severely affects the lifespan of the optical module.

### SUMMARY OF THE DISCLOSURE

### Technical Problem

Based on this, it is necessary to provide an optical module and an optical communication device to solve the problem of poor internal heat dissipation effect of the existing optical module.

### Technical Solutions

An optical module is provided, including a first housing, a second housing, an optoelectronic component and a circuit board, wherein the optoelectronic component and the circuit board are installed between the first housing and the second housing, the optoelectronic component is thermally connected to the first housing or the second housing, and both the first housing and the second housing have bottom walls and side walls, wherein:
the first housing has a first protrusion on the bottom wall facing a side of the second housing, and the first protrusion has a first mating surface;
a second mating surface is provided on the bottom wall of the second housing, and the first mating surface is thermally connected to the second mating surface.

The above-mentioned optical module is installed on an external switch with the first housing as the main heat dissipation surface, and has a first protrusion on the bottom wall of the first housing. When the first mating surface and the second mating surface are thermally connected, the heat generated by the optoelectronic component during operation can be conducted to the bottom wall of the first housing through the first protrusion, and the heat concentrated on the second housing can also be conducted to the bottom wall of the first housing through the first protrusion and transmitted to the external environment through the bottom wall of the first housing. The optical module is provided with a first protrusion at the internal gap, which rationally utilizes the internal space of the optical module without increasing the volume of the optical module. Compared with the traditional air heat conduction method, the optical module increases the contact area between the first housing and the second housing and uses a solid heat conduction method to accelerate the heat conduction rate, so as to quickly dissipate the heat concentrated on the second housing, reduce the temperature gradient difference between the first housing and the second housing, and significantly improve the heat dissipation effect of the optical module.

In one embodiment, a plurality of first protrusions are provided, and the plurality of first protrusions are distributed around the optoelectronic component.

In one embodiment, a second protrusion is provided on the bottom wall of the second housing, and the second mating surface is located on the second protrusion.

In one embodiment, the first mating surface is a bevel or a sawtooth surface, and the second mating surface is also a bevel or a sawtooth surface matching the first mating surface.

In one embodiment, a thermally conductive adhesive is provided between the first mating surface and the second mating surface.

In one embodiment, an optoelectronic chip is disposed on the circuit board, a third protrusion is provided on the bottom wall of the side of the second housing facing the circuit board, and the third protrusion is thermally connected to the optoelectronic chip.

In one embodiment, the first housing and the first protrusion are integrally formed.

In one embodiment, the first protrusion penetrates the circuit board and is thermally connected to the second mating surface.

In one embodiment, the optical module further includes a carrier plate fixed on the circuit board, the carrier plate is thermally connected to the first housing, and the optoelectronic component is a laser chip and is arranged on the carrier board.

An optical communication device is provided, characterized by comprising any one of the aforementioned optical modules.

### Beneficial Effects

In the above-mentioned optical communication device, the heat generated by the optoelectronic component during operation can be conducted to the bottom wall of the first housing through the first protrusion, and the heat concentrated on the second housing can also be conducted to the bottom wall of the first housing through the first protrusion and transmitted to the external environment through the bottom wall of the first housing. The optical module is provided with a first protrusion at the internal gap, which rationally utilizes the internal space of the optical module without increasing the volume of the optical module. Compared with the traditional air heat conduction method, the optical module increases the contact area between the first housing and the second housing and uses a solid heat conduction method to accelerate the heat conduction rate, so as to quickly dissipate the heat concentrated on the second housing, reduce the temperature gradient difference between the first housing and the second housing, and significantly improve the heat dissipation effect of the optical module.

### BRIEF DESCRIPTION OF THE DRAWINGS

FIG. 1 is an exploded schematic diagram of the optical module provided by the present disclosure;

FIG. 2 is a schematic diagram of the internal structure of the optical module provided by the present disclosure;

FIG. 3 is a schematic diagram of the cooperation between the first protrusion and the second protrusion in one embodiment;

FIG. 4 is a schematic diagram of the cooperation between the first protrusion and the second protrusion in another embodiment.

### REFERENCE SIGNS

100. Optical module;
110. First housing; 111. First protrusion; 112. First mating surface;
120. Second housing; 121. Second protrusion; 122. Second mating surface; 123. Third protrusion;
130. Optoelectronic component;
140. Circuit board; 141. Optoelectronic chip;
150. Bottom wall;
160. Side wall;
170. Carrier board.

### DETAILED DESCRIPTION OF THE EXEMPLARY EMBODIMENTS

In order to make the above objects, features and advantages of the present disclosure more obvious and easy to understand, the specific implementation modes of the present disclosure will be described in detail below with reference to the accompanying drawings. In the following description, numerous specific details are set forth to facilitate a thorough understanding of the present disclosure. However, the present disclosure can be implemented in many other ways different from those described here. Those skilled in the art can make similar improvements without violating the connotation of the present disclosure. Therefore, the present disclosure is not limited to the specific embodiments disclosed below.

In the description of the present disclosure, it should be understood that the terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, “axis””, “radial direction”, “circumferential direction”, etc. indicate the orientation or positional relationship based on the orientation or positional relationship shown in the drawings. They are only for the convenience of describing the present disclosure and simplifying the description, and do not indicate or imply what is meant. Devices or components must have a specific orientation, be constructed and operate in a specific orientation and therefore are not to be construed as limitations of the invention.

In addition, the terms “first” and “second” are used for descriptive purposes only and cannot be understood as indicating or implying relative importance or implicitly indicating the quantity of indicated technical features. Therefore, features defined as “first” and “second” may explicitly or implicitly include at least one of these features. In the description of the present disclosure, “plurality” means at least two, such as two, three, etc., unless otherwise clearly and specifically limited.

In the present disclosure, unless otherwise expressly stipulated and limited, the terms “installation”, “connection”, “connection”, “fixing” and other terms should be understood in a broad sense. For example, it can be a fixed connection, a detachable connection, or an integral connection; it can be a mechanical connection or an electrical connection; it can be a direct connection or an indirect connection through an intermediate medium, it can be the internal connection of two elements or the interaction relationship between two elements, unless otherwise clearly defined. For ordinary technicians in this field, the specific meanings of the above terms in the present disclosure can be understood according to specific circumstances.

In the present disclosure, unless otherwise expressly stipulated and limited, a first feature being “above” or “below” a second feature may mean that the first and second features are in direct contact, or the first and second features are in indirect contact through an intermediate medium. Moreover, a first feature being “on”, “above” or “beyond” a second feature may mean that the first feature is directly above or obliquely above the second feature, or simply means that the first feature is higher in level than the second feature. A first feature being “below”, “under” or “beneath” a second feature may mean that the first feature is directly below or obliquely below the second feature, or simply means that the first feature is lower in level than the second feature.

It should be noted that when an element is referred to as being “mounted” or “disposed on” another element, it can be directly on the other element or intervening elements may also be present. When an element is said to be “connected” to another element, it can be directly connected to the other element or there may also be intervening elements present. The terms “vertical”, “horizontal”, “upper”, “lower”, “left”, “right” and similar expressions used herein are for illustrative purposes only and do not represent the only implementation manner.

The technical solutions provided by the embodiments of present disclosure will be introduced below with reference to the accompanying drawings.

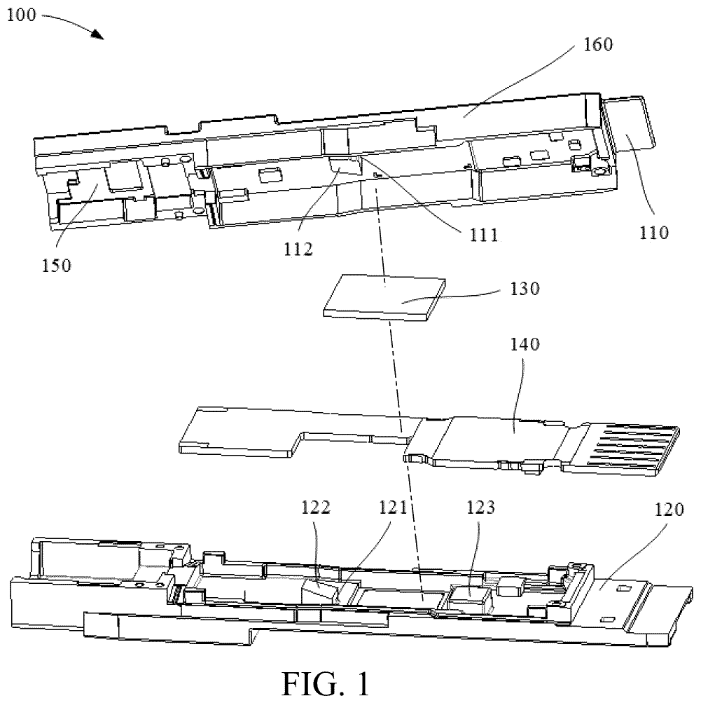

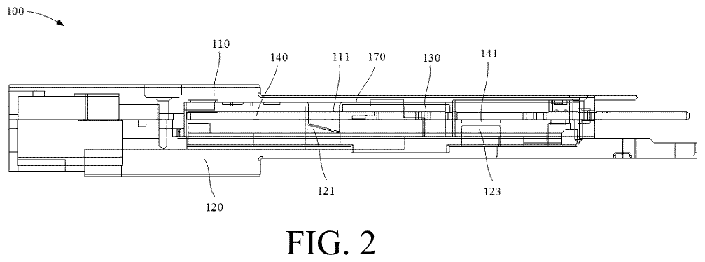

As shown in FIGS. 1 and 2, the present disclosure provides an optical module 100 for use with an external switch. The optical module 100 includes a first housing 110, a second housing 120, an optoelectronic component 130 and a circuit board 140. The optoelectronic component 130 is installed between the first housing 110 and the second housing 120 through snapping, adhesion, etc., and the circuit board 140 is also installed between the first housing 110 and the second housing 120 through snapping, bonding, etc., to realize the installation and fixation of the optoelectronic component 130 and the circuit board 140. The first housing 110 has a bottom wall 150 and a side wall 160, that is, the bottom wall 150 and the side wall 160 together form the first housing 110. Similarly, the second housing 120 also has a bottom wall 150 and a side wall 160, that is, the bottom wall 150 and the side wall 160 together form the second housing 120. During operation, the light emitting component of the optoelectronic component 130 first converts the electrical signal into an optical signal. The light receiving component of the optoelectronic component 130 then converts the optical signal into an electrical signal, and outputs the electrical signal to the switch outside the optical module 100 through the circuit board 140. Moreover, the optoelectronic component 130 is thermally connected to the first housing 110, or the optoelectronic component 130 is thermally connected to the second housing 120, so as to conduct the heat generated by the optoelectronic component 130 during operation to the first housing 110 or the second housing 120.

Specifically, the first protrusion 111 is provided on the bottom wall 150 of the first housing 110, and the first protrusion 111 has a first mating surface 112. The first protrusion 111 penetrates the circuit board 140 to provide the first protrusion 111 at an internal gap of the optical module 100 to fully utilize the internal space of the optical module 100. The first protrusion 111 and the first housing 110 are integrally formed by extrusion, casting, etc., so as to simplify the molding method of the first housing 110 and save the manufacturing cost of the first housing 110. Certainly, the first housing 110 can also be formed with the first protrusion 111 by welding or other methods. The present disclosure does not limit the specific forming method of the first housing 110 and the first protrusion 111.

The bottom wall 150 of the second housing 120 has a second mating surface 122. The first mating surface 112 and the second mating surface 122 are thermally connected together, so as to realize that the first protrusion 111 and the second housing 120 can cooperate with each other. It should be noted that the first mating surface 112 is in contact with the second mating surface 122 through bonding, snapping, etc., and a thermal conductive medium is provided between the first mating surface 112 and the second mating surface 122 to thermally connect the first mating surface 112 and the second mating surface 122.

The above-mentioned optical module 100 is installed on an external switch with the bottom wall 150 of the first housing 110 as the main heat dissipation surface. The heat generated by the optoelectronic component 130 during operation can be conducted to the first housing 110 through the first protrusion 111, and the heat concentrated on the second housing 120 can also be conducted to the bottom wall 150 of the first housing 110 through the first protrusion 111 and to the external environment through the bottom wall 150 of the first housing 110. The optical module 100 is provided with a first protrusion 111 at an internal gap, which rationally utilizes the internal space of the optical module 100 without increasing the volume of the optical module 100. Compared with the traditional air heat conduction method, the optical module 100 increases the contact area between the first housing 110 and the second housing 120, and uses a solid heat conduction method to accelerate the heat conduction rate. Since the second housing 120 is far away from the main heat dissipation surface, the heat dissipation effect of the second housing 120 is poor. The first protrusion 111 can quickly dissipate the heat concentrated on the second housing 120, reduce the temperature gradient difference between the first housing 110 and the second housing 120, and significantly improve the heat dissipation effect of the optical module 100.

In order to further improve the heat dissipation effect of the optical module 100, as shown in FIGS. 1 and 2, a plurality of first protrusions 111 are provided, and the plurality of first protrusions 111 are distributed around the optoelectronic component 130. In other words, the plurality of first protrusions 111 are distributed at intervals in the gaps of the first housing 110, which can reasonably utilize the internal space of the optical module 100 without increasing the volume of the optical module 100. In addition, the plurality of first protrusions 111 can promptly take away the heat generated by the optoelectronic component 130 during operation to further increase the thermal conductivity rate inside the optical module 100, thereby improving the heat dissipation effect of the optical module 100.

In addition, a second protrusion 121 is provided on the bottom wall 150 of the second housing 120, and the second mating surface 122 is located on the second protrusion 121. That is, when the first mating surface 112 and the second mating surface 122 are thermally connected, the first protrusion 111 is connected with the second protrusion 121. The heat concentrated on the second housing 120 can be conducted to the first protrusion 111 through the second protrusion 121, then conducted to the bottom wall 150 of the first housing 110 through the first protrusion 111, and quickly transmitted to the external environment through the first housing 110, thereby reducing the temperature gradient difference between the first housing 110 and the second housing 120 to significantly improve the heat dissipation effect of the optical module 100.

Similarly, a plurality of second protrusions 121 and the second housing 120 are integrally formed by extrusion, casting, etc., to simplify the molding method of the second housing 120 and save the manufacturing cost of the second housing 120. Certainly, the second housing 120 can also be formed with the plurality of second protrusions 121 by welding or other methods. The present disclosure does not limit the specific forming method of the second housing 120 and the second protrusion 121.

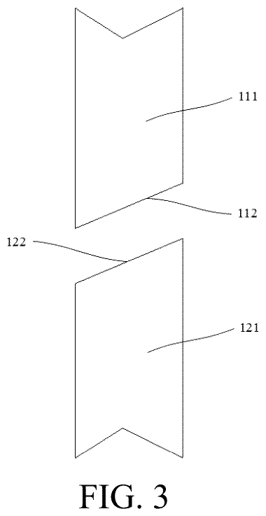

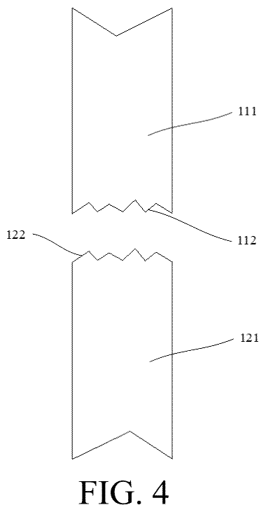

In order to further improve the heat dissipation effect of the optical module 100, as shown in FIGS. 1 and 2, the first mating surface 112 is a special-shaped surface, and specifically, it can be one of a bevel or a sawtooth surface. The second matching surface 122 is also a special-shaped surface, and specifically, it can also be one of a beveled surface or a sawtooth surface. It should be noted that, as shown in FIG. 3, when the first mating surface 112 is a bevel, the second mating surface 122 is also a bevel. As shown in FIG. 4, when the first mating surface 112 is a sawtooth surface, the second mating surface 122 is also a sawtooth surface. Moreover, the first mating surface 112 and the second mating surface 122 have a unique joining direction. The first mating surface 112 and the second mating surface 122 are mated so that when the first housing 110 and the second housing 120 are connected, the first mating surface 112 and the second mating surface 122 can be used as guide surfaces to improve the mating accuracy and mating efficiency of the first housing 110 and the second housing 120. Since the special-shaped surface has a larger contact area within the same unit volume, by setting both the first mating surface 112 and the second mating surface 122 as a special-shaped surface, the contact area between the first housing 110 and the second housing 120 can be further increased, the heat conduction efficiency can be accelerated, and the heat dissipation effect of the optical module 100 can be further improved.

It should be noted that the first mating surface 112 and the second mating surface 122 are not limited to a bevel or a sawtooth surface provided above, and may also be corrugated surfaces or other surfaces that can increase the contact area between the first protrusion 111 and the second protrusion 121. Regarding the surface of the contact area, the present disclosure does not limit the specific shapes of the first mating surface 112 and the second mating surface 122.

In order to achieve thermal conductive connection between the first mating surface 112 and the second mating surface 122, as shown in FIGS. 1 and 2, a thermally conductive adhesive (not shown) is provided between the first mating surface 112 and the second mating surface 122. The thermally conductive adhesive can realize the connection between the first protrusion 111 and the second protrusion 121, and the thermally conductive adhesive can conduct heat and help dissipate the internal heat of the optical module 100.

In order to further improve the heat dissipation effect of the optical module 100, as shown in FIGS. 1 and 2, the circuit board 140 also includes an optoelectronic chip 141, the bottom wall 150 of the second housing 120 has a third protrusion 123, a third protrusion 123 is located on the side of the second housing 120 facing the circuit board 140, and the third protrusion 123 is thermally connected to the optoelectronic chip 141. Since the heat of the optoelectronic chip 141 is particularly serious during the operation of the circuit board 140, the heat of the optoelectronic chip 141 can be conducted to the second housing 120 through the third protrusion 123, and to the bottom wall 150 of the first housing 110 through the second protrusion 121 and the first protrusion 111. Compared with the traditional air heat conduction method, the solid heat conduction method of the third protrusion 123, the second protrusion 121, and the first protrusion 111 has better heat conduction performance, which can accelerate the heat dissipation of the optoelectronic chip 141 and further improve the heat dissipation effect of the optical module 100. The optoelectronic chip 141 can be one of an optical chip or an electrical chip, and the type of the optoelectronic chip 141 can be selected according to user needs.

In order to further dissipate the heat generated by the optical module 100 during operation, as shown in FIGS. 1 and 2, the optical module 100 also includes a carrier board 170, and the circuit board 140 is fixed on the carrier board 170 by screwing or welding to realize the installation and fixation of the circuit board 140. Moreover, the optoelectronic component 130 is a laser chip, and the optoelectronic component 130 is disposed on the carrier board 170 through screwing, welding, etc., to realize the installation and fixation of the optoelectronic component 130. The carrier board 170 is thermally connected to the first housing 110, so that the heat generated by the optoelectronic component 130 and the circuit board 140 during operation can be promptly transferred to the carrier board 170, then transferred to the first housing 110 through the carrier board 170, and conducted to the external environment through the first housing 110, thereby further quickly dissipating the heat generated by the optical module 100 during operation.

Moreover, as shown in FIGS. 1 and 2, the first protrusion 111 is made of one of aluminum material or copper material, and similarly, the second protrusion 121 and the third protrusion 123 are also made of one of aluminum material or copper material. On the one hand, aluminum and copper both have good thermal conductivity, ensuring that the heat generated by the optical module 100 can be quickly transferred to the external environment through the first protrusion 111, the second protrusion 121 and the third protrusion 123, thereby accelerating the dissipation of the heat generated in the optical module 100 and improving the heat dissipation effect of the optical module 100. On the other hand, the cost of aluminum and copper is relatively low, which can save the manufacturing cost of the optical module 100.

Certainly, the first protrusion 111, the second protrusion 121 and the third protrusion 123 are not limited to being made of the aluminum material or copper material provided above, and can also be made of silver material, gold material or other materials with good thermal conductivity. The present disclosure does not limit the specific materials of the first protrusion 111, the second protrusion 121 and the third protrusion 123, and can be specifically selected according to actual needs, as long as the thermal conductivity of the first protrusion 111, the second protrusion 121 and the third protrusion 123 is good.

In addition, the present disclosure also provides an optical communication device. The optical communication device includes the optical module 100 according to any one of the above technical solutions.

The aforementioned optical communication device utilizes the first protrusion 111 to conduct the heat generated by the optoelectronic component 130 during operation to the bottom wall 150 of the first housing 110. Additionally, the heat concentrated on the second housing 120 can also be conducted via the first protrusion 111 to the bottom wall 150 of the first housing 110, and then dissipated to the external environment through the bottom wall 150 of the first housing 110. The optical communication device is provided with a first protrusion at the internal gap, which rationally utilizes the internal space of the optical communication device without increasing the volume of the optical communication device. Compared with the traditional air heat conduction method, the optical communication device increases the contact area between the first housing 110 and the second housing 120 and uses a solid heat conduction method to accelerate the heat conduction rate, so as to quickly dissipate the heat concentrated on the second housing 120, reduce the temperature gradient difference between the first housing 110 and the second housing 120, and significantly improve the heat dissipation effect of the optical communication device.

The technical features of the above-described embodiments can be combined in any way. To simplify the description, not all possible combinations of the technical features in the above-described embodiments are described. However, as long as there is no contradiction in the combination of these technical features, all should be considered to be within the scope of the present specification.

The above-mentioned embodiments only express several implementation modes of the present disclosure. The descriptions are relatively specific and detailed, but they should not be construed as limiting the scope of present disclosure. It should be noted that for those of ordinary skill in the art, several modifications and improvements can be made without departing from the concept of the present disclosure, and these all fall within the protection scope of the present disclosure. Therefore, the protection scope of present disclosure should be determined by the appended claims.

1. An optical module, including a first housing, a second housing, an optoelectronic component and a circuit board, wherein the optoelectronic component and the circuit board are installed between the first housing and the second housing, the optoelectronic component is thermally connected to the first housing or the second housing, and both the first housing and the second housing have bottom walls and side walls, wherein:
the first housing has a first protrusion on the bottom wall facing a side of the second housing, and the first protrusion has a first mating surface;
a second mating surface is provided on the bottom wall of the second housing, and the first mating surface is thermally connected to the second mating surface.

2. The optical module according to claim 1, wherein a plurality of first protrusions are provided, and the plurality of first protrusions are distributed around the optoelectronic component.

3. The optical module according to claim 1, wherein a second protrusion is provided on the bottom wall of the second housing, and the second mating surface is located on the second protrusion.

4. The optical module according to claim 1, wherein the first mating surface is a bevel or a sawtooth surface, and the second mating surface is also a bevel or a sawtooth surface matching the first mating surface.

5. The optical module according to claim 1, wherein a thermally conductive adhesive is provided between the first mating surface and the second mating surface.

6. The optical module according to claim 1, wherein an optoelectronic chip is disposed on the circuit board, a third protrusion is provided on the bottom wall of the side of the second housing facing the circuit board, and the third protrusion is thermally connected to the optoelectronic chip.

7. The optical module according to claim 1, wherein the first housing and the first protrusion are integrally formed.

8. The optical module according to claim 1, wherein the first protrusion penetrates the circuit board and is thermally connected to the second mating surface.

9. The optical module according to claim 1, wherein the optical module further includes a carrier plate fixed on the circuit board, the carrier plate is thermally connected to the first housing, and the optoelectronic component is a laser chip and is arranged on the carrier board.

10. An optical communication device, characterized by comprising the optical module according to claim 1.
